(19) United States
(12) Patent Application Publication
(10) Pub. No.: US 2022/0019298 A1
(43) Pub. Date: Jan. 20, 2022

(54) HOUSING INCLUDING CONDUCTIVE PART, AND ELECTRONIC DEVICE INCLUDING SAME

(71) Applicant: Samsung Electronics Co., Ltd., Suwon-si, Gyeonggi-do (KR)

(72) Inventors: Minsoo KIM, Suwon-si (KR); Kwangho SHIN, Suwon-si (KR); Museok BANG, Suwon-si (KR); Hyunsuk CHOI, Suwon-si (KR)

(21) Appl. No.: 17/309,351

(22) PCT Filed: Nov. 21, 2019
(86) PCT No.: PCT/KR2019/016003

§ 371 Date: May 20, 2021

(30) Foreign Application Priority Data
Nov. 21, 2018 (KR) 10-2018-0144661

(51) Int. Cl. G06F 3/0354; G06F 3/038

(52) U.S. Cl. CPC G06F 3/03545; H05K 1/115; G06F 3/038

(57) ABSTRACT

Various embodiments disclosed in the present document relate to an electronic device (for example, an input device) for communication with an external electronic device. According to various embodiments of the present document, provided is an electronic device (for example, an input device) comprising: a housing which is extended to be long while forming a first inner space extended to be long, and which includes a first end part, a second end part, and a conductive portion arranged between the first end part and the second end part; an inner structure, which is positioned in the first inner space, has at least one portion arranged in the conductive part of the housing, and forms a second inner space extended to be long; a first conductive layer formed on the outer surface of the inner structure while facing the inner surface of the conductive part of the housing; a non-conductive layer configured to contact with the first conductive layer and the inner surface of the conductive part of the housing; and a wireless communication circuit positioned in the second inner space, electrically connected to the first conductive layer, and configured to wirelessly transmit and/or receive signals by using at least a portion of the conductive part. Additional various embodiments can be provided.

### CROSS-REFERENCE TO RELATED APPLICATIONS

This application is a National Phase Entry of PCT International Application No. PCT/KR2019/016003, which was filed on Nov. 21, 2019 and claims priority to Korean Patent Application No. 10-2018-0144661, which was filed on Nov. 21, 2018 in the Korean Intellectual Property Office, the contents of which are incorporated herein by reference.

### BACKGROUND

### 1. Field

Various embodiments of the disclosure relate to an electronic device (e.g., an input device) for communicating with an external electronic device.

### 2. Description of the Related Art

Smartphones, tablet PCs, or other portable electronic devices are recently in wide use, and vigorous efforts are underway to develop pen input devices applicable to portable electronic devices. A smartphone or tablet PC mainly includes a touchscreen, and the user may designate specific coordinates on the touch screen using her finger or a pen input device. The user may input a specific signal to the smartphone by designating specific coordinates on the touchscreen.

The touchscreen may be operated based on an electrical, infrared, or ultrasonic scheme. Touchscreens adopting the electrical scheme include, e.g., resistive touchscreens (also known as R-type touchscreens) or capacitive touchscreens (also known as C-type touchscreens). Among the touch screens, R-type touch screens that may simultaneously recognize the user's finger and pen have conventionally been widely used, but use of C-type touch screens are recently on the rise due to reflection issues caused by the air layer between the ITO layers found in R-type touch screens. The C-type touch screen works to detect a difference in capacitance of the transparent electrode generated by contact with an object. However, the C-type touch screen may cause operation errors due to unintended hand contact when using the pen because it is difficult to physically distinguish between a hand and a pen.

As conventional techniques for mitigating these drawbacks, there are a method for distinguishing between hand and pen by software according to the contact area or by measuring the position of the pen using a magnetic field signal according to an electro-magnetic resonance (EMR) method. Also adopted is an electrically coupled resonance (ECR) method that receives the electric field from the pen and measures the position of the pen.

### SUMMARY

For example, an input device having an EMR-type pen function, by its design structure, has an EMR coil unit in a pen tip area and a charging unit for charging power in an area behind the coil unit. Further, an antenna unit for data communication between the electronic device and the pen input device may be placed in an area behind the charging unit considering the locations of electronic components and circuit components and the area gripped by hand and/or its frequency.

An input device having a pen function may exchange data with an electronic device (e.g., a smart phone) through short-range communication (e.g., Bluetooth low energy (BLE)). The user of the electronic device may perform various functions (e.g., sketching or running various applications) using an input device interworking with the electronic device. According to a recent trend of miniaturizing electronic devices and input devices, methods for assembling and/or mounting various electronic devices or circuit components embedded in an electronic device and an input device draw attention from the point of view of minimizing power consumption and enhancing communication efficiency.

Further, input devices are nowadays recognized as a design element that evokes an aesthetic sense from the user, but rather merely as an input means. For example, metal may be employed as a material of the housing of the input device according to demand for differentiated design and innovation.

For communication efficiency, pen input devices according to some embodiments may not exhibit the optimal antenna performance due to the material of the housing. For example, when a metal housing is applied to a pen input device, the signals radiated from the antenna may be electromagnetically interfered by the metal housing, posing a limitation to designing antennas.

For assembly of components, some issues may arise upon applying a metal housing to pen input devices according to some embodiments. For example, the contact part may be scratched and/or cut or damaged while inserting and assembling components (e.g., a printed circuit board and a contact structure on the printed circuit board) in the inner space of the housing. If such damage is exposed to moisture, corrosion may occur along with poor contact in the structure requiring electrical connection.

According to various embodiments of the disclosure, there may be provided an input device (or electronic device) adopting a metal housing, which may reduce electromagnetic interference for seamless communication between an electronic device and the input device.

According to various embodiments of the disclosure, there may be provided an electronic device that may address contact failure and damage.

According to various embodiments of the disclosure, there may be provided an electronic device, comprising an elongated housing forming an elongated first inner space, the housing including a first end, a second end, and a conductive part disposed between the first end and the second end, an internal structure positioned in the first inner space, at least a portion of the internal structure disposed in the conductive part of the housing and forming an elongated second inner space, a first conductive layer facing an inner surface of the conductive part of the housing and formed on an outer surface of the internal structure, a non-conductive layer configured to contact the first conductive layer and the inner surface of the conductive part of the housing, and a wireless communication circuit positioned in the second inner space, electrically connected with the first conductive layer, and configured to wirelessly transmit and/or receive a signal using at least a portion of the conductive part.

According to various embodiments of the disclosure, there may be provided an electronic device comprising a first housing including a first plate, a second plate facing away from the first plate, and a side member surrounding a receiving space between the first plate and the second plate, an elongated receiving hole formed in the side member and connected with the receiving space, and an input device inserted into the receiving hole or removable from the receiving hole, wherein the input device comprises an elongated second housing forming an elongated first inner space, the second housing including a first end, a second end, and a conductive part disposed between the first end and the second end, an internal structure positioned in the first inner space, at least a portion of the internal structure disposed in the conductive part of the second housing and forming an elongated second inner space, a first conductive layer facing an inner surface of the conductive part of the second housing and formed on an outer surface of the internal structure, a non-conductive layer formed to contact the first conductive layer and the inner surface of the conductive part of the second housing, and a wireless communication circuit positioned in the second inner space, electrically connected with the first conductive layer, and configured to wirelessly transmit and/or receive a signal using at least a portion of the conductive part.

According to various embodiments of the disclosure, it is possible to provide a pen input device for actively communicating with an electronic device, but not a pen input device having a passive configuration for inputting a pen by simply pressing an electronic device having a display.

According to various embodiments of the disclosure, in an input device (e.g., a stylus pen) adopting a metal material in a housing, electronic components or circuit components may be mounted on each of a first surface and a second surface of a printed circuit board to utilize a limited inner space and meet the antenna performance index and waterproof performance.

### BRIEF DESCRIPTION OF THE DRAWINGS

FIG. 1 is a front perspective view illustrating an electronic device according to various embodiments;

FIG. 2 is a rear perspective view illustrating the electronic device of FIG. 1;

FIG. 3 is an exploded perspective view illustrating the electronic device of FIG. 1;

FIG. 4A is a perspective view illustrating an electronic device according to various embodiments and an example in which a portion of an input device is inserted into the electronic device according to various embodiments;

FIG. 4B is a perspective view illustrating an input device according to various embodiments;

FIG. 4C is a perspective view illustrating various examples of a housing of an input device;

FIG. 5 is an exploded perspective view illustrating an input device according to various embodiments;

FIG. 6 is a cross-sectional view illustrating a portion of an input device according to various embodiments;

FIG. 7A is a perspective view illustrating an input device according to an embodiment different from that of FIG. 5;

FIG. 7B is a cross-sectional view illustrating the first conductive layer (e.g., a waterproof contact face portion) of FIG. 7A according to various embodiments;

FIG. 8 is a cross-sectional view illustrating a second conductive layer, a conductive via, and a flexible conductive member of an input device according to various embodiments;

FIG. 9 is a view illustrating a wireless communication circuit of an input device according to various embodiments;

FIG. 10 is a view illustrating a circuit structure of an input device according to various embodiments;

FIG. 11 is a view illustrating a mold part and a third conductive layer of an input device according to various embodiments;

FIG. 12 is a view illustrating an example in which an elastic member is formed in a mold part of an input device according to various embodiments;

FIG. 13 is a graph illustrating an antenna radiation performance index of an input device according to various embodiments; and

FIG. 14 is a block diagram illustrating an electronic device in a network environment according to various embodiments.

The same or similar reference denotations may be used to refer to the same or similar elements throughout the specification and the drawings.

### DETAILED DESCRIPTION

Hereinafter, embodiments of the present disclosure are described with reference to the accompanying drawings.

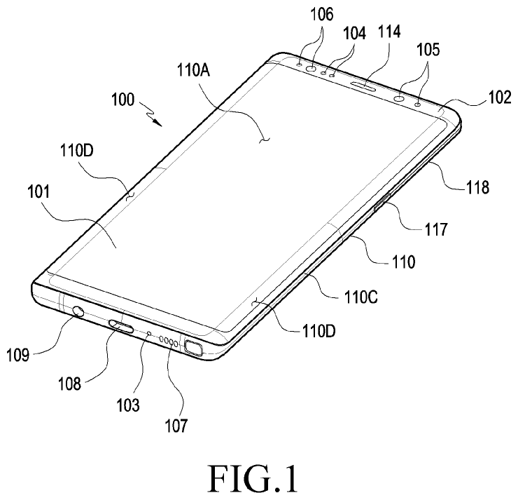

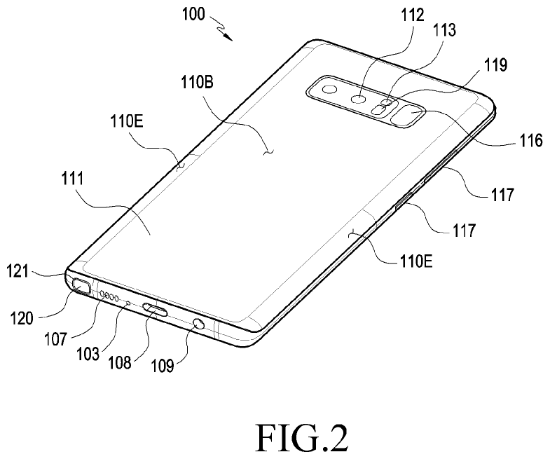

Referring to FIGS. 1 and 2, according to an embodiment, an electronic device 100 may include a housing 110 with a first (or front) surface 110A, a second (or rear) surface 110B, and a side surface 110C surrounding a space between the first surface 110A and the second surface 110B. According to another embodiment (not shown), the housing may denote a structure forming part of the first surface 110A, the second surface 110B, and the side surface 110C of FIG. 1. According to an embodiment, at least part of the first surface 110A may have a substantially transparent front plate 102 (e.g., a glass plate or polymer plate including various coat layers). The second surface 110B may be formed by a rear plate 111 that is substantially opaque. The rear plate 111 may be formed of, e.g., laminated or colored glass, ceramic, polymer, metal (e.g., aluminum, stainless steel (STS), or magnesium), or a combination of at least two thereof. The side surface 110C may be formed by a side bezel structure (or a “side member”) 118 that couples to the front plate 102 and the rear plate 111 and includes a metal and/or polymer. According to an embodiment, the rear plate 111 and the side bezel plate 118 may be integrally formed together and include the same material (e.g., a metal, such as aluminum).

In the embodiment illustrated, the front plate 102 may include two first regions 110D, which seamlessly and bendingly extend from the first surface 110A to the rear plate 111, on both the long edges of the front plate 102. In the embodiment (refer to FIG. 2) illustrated, the rear plate 111 may include second regions 110E, which seamlessly and bendingly extend from the second surface 110B to the front plate 102, on both the long edges. According to an embodiment, the front plate 102 (or the rear plate 111) may include only one of the first regions 110D (or the second regions 110E). Alternatively, the first regions 110D or the second regions 110E may partially be excluded. According to an embodiment, at side view of the electronic device 100, the side bezel structure 118 may have a first thickness (or width) for sides that do not have the first regions 110D or the second regions 110E and a second thickness, which is smaller than the first thickness, for sides that have the first regions 110D or the second regions 110E.

According to an embodiment, the electronic device 100 may include at least one or more of a display 101, audio modules 103, 107, and 114, sensor modules 104, 116, and 119, camera modules 105, 112, and 113, key input devices 117, a light emitting device 106, a pen input device 120, and connector holes 108 and 109. According to an embodiment, the electronic device 100 may exclude at least one (e.g., the key input device 117 or the light emitting device 106) of the components or may add other components.

The display 101 may be exposed through the top of, e.g., the front plate 102. According to an embodiment, at least a portion of the display 101 may be exposed through the front plate 102 forming the first surface 110A and the first regions 110D of the side surface 110C. According to an embodiment, the edge of the display 101 may be formed to be substantially the same in shape as an adjacent outer edge of the front plate 102. According to an embodiment (not shown), the interval between the outer edge of the display 101 and the outer edge of the front plate 102 may remain substantially even to give a larger area of exposure the display 101.

According to another embodiment (not shown), the screen display region of the display 101 may have a recess or opening in a portion thereof, and at least one or more of the audio module 114, sensor module 104, camera module 105, and light emitting device 106 may be aligned with the recess or opening. According to another embodiment (not shown), at least one or more of the audio module 114, sensor module 104, camera module 105, fingerprint sensor 116, and light emitting device 106 may be included on the rear surface of the screen display region of the display 101. According to another embodiment (not shown), the display 101 may be disposed to be coupled with, or adjacent, a touch detecting circuit, a pressure sensor capable of measuring the strength (pressure) of touches, and/or a digitizer for detecting a magnetic field-type stylus pen. According to an embodiment, at least part of the sensor modules 104 and 119 and/or at least part of the key input device 117 may be disposed in the first regions 110D and/or the second regions 110E.

The audio modules 103, 107, and 114 may include a microphone hole 103 and speaker holes 107 and 114. The microphone hole 103 may have a microphone inside to obtain external sounds. According to an embodiment, there may be a plurality of microphones to be able to detect the direction of a sound. The speaker holes 107 and 114 may include an external speaker hole 107 and a phone receiver hole 114. According to an embodiment, the speaker holes 107 and 114 and the microphone hole 103 may be implemented as a single hole, or speakers may be rested without the speaker holes 107 and 114 (e.g., piezo speakers).

The sensor modules 104, 116, and 119 may generate an electrical signal or data value corresponding to an internal operating state or external environmental state of the electronic device 100. The sensor modules 104, 116, and 119 may include a first sensor module 104 (e.g., a proximity sensor) and/or a second sensor module (not shown) (e.g., a fingerprint sensor) disposed on the first surface 110A of the housing 110 and/or a third sensor module 119 (e.g., a heart-rate monitor (HRM) sensor) and/or a fourth sensor module 116 (e.g., a fingerprint sensor) disposed on the second surface 110B of the housing 110. The fingerprint sensor may be disposed on the second surface 110A as well as on the first surface 110B (e.g., the display 101) of the housing 110. The electronic device 100 may further include sensor modules not shown, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 104.

The camera modules 105, 112, and 113 may include a first camera device 105 disposed on the first surface 110A of the electronic device 100, and a second camera device 112 and/or a flash 113 disposed on the second surface 110B. The camera modules 105 and 112 may include one or more lenses, an image sensor, and/or an image signal processor. The flash 113 may include, e.g., a light emitting diode (LED) or a xenon lamp. According to an embodiment, two or more lenses (an infrared (IR) camera, a wide-angle lens, and a telescopic lens) and image sensors may be disposed on one surface of the electronic device 100.

The key input device 117 may be disposed on the side surface 110C of the housing 110. According to an embodiment, the electronic device 100 may exclude all or some of the above-mentioned key input devices 117 and the excluded key input devices 117 may be implemented in other forms, e.g., as soft keys, on the display 101. According to an embodiment, the key input device may include the sensor module 116 disposed on the second surface 110B of the housing 110.

The light emitting device 106 may be disposed on, e.g., the first surface 110A of the housing 110. The light emitting device 106 may provide, e.g., information about the state of the electronic device 100 in the form of light. According to an embodiment, the light emitting device 106 may provide a light source that interacts with, e.g., the camera module 105. The light emitting device 106 may include, e.g., a light emitting device (LED), an infrared (IR) LED, or a xenon lamp.

The connector holes 108 and 109 may include a first connector hole 108 for receiving a connector (e.g., a universal serial bus (USB) connector) for transmitting or receiving power and/or data to/from an external electronic device and/or a second connector hole 109 (e.g., an earphone jack) for receiving a connector for transmitting or receiving audio signals to/from the external electronic device.

The pen input device 120 (e.g., a stylus pen) may be guided and detachably inserted through a hole 121 formed in a side surface of the housing 110 into the inside of the housing 110. The pen input device 120 may include a button for easy detachment. A separate resonance circuit may be embedded in the pen input device 120 and may interwork with an electromagnetic induction panel 390 (e.g., a digitizer) included in the electronic device 100. The pen input device 120 may come in, e.g., an EMR scheme, an active electrical stylus (AES) scheme, or an ECR scheme.

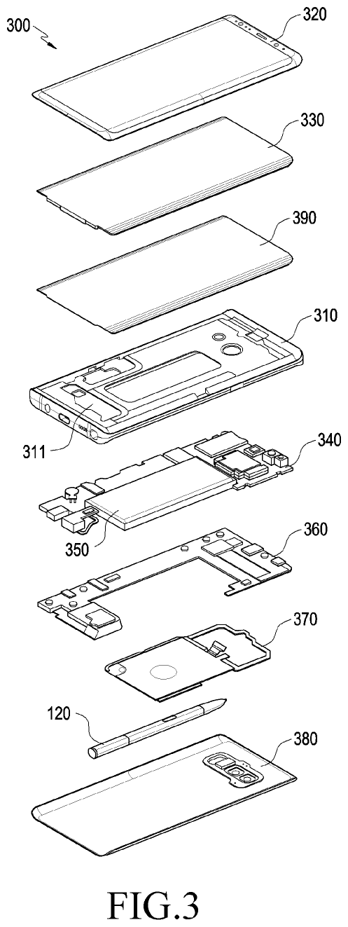

Referring to FIG. 3, an electronic device 300 may include a side bezel structure 310, a first supporting member 311 (e.g., a bracket), a front plate 320, a display 330, an electromagnetic induction panel 390, a printed circuit board 340, a battery 350, a second supporting member 360 (e.g., a rear case), an antenna 370, a pen input device 120, and a rear plate 380. According to an embodiment, the electronic device 300 may exclude at least one (e.g., the first supporting member 311 or second supporting member 360) of the components or may add other components. At least one of the components of the electronic device 300 may be the same or similar to at least one of the components of the electronic device 100 of FIG. 1 or 2 and no duplicate description is made below.

The electromagnetic induction panel 390 (e.g., a digitizer) may be a panel for detecting input by the pen input device 120. For example, the electromagnetic induction panel 390 may include a printed circuit board (FPCB) and a shielding sheet. The shielding sheet may prevent inter-component interference by an electromagnetic field produced from the components (e.g., the display module, PCB, or electromagnetic induction panel) included in the electronic device 100. The shielding sheet may shield off electromagnetic fields produced from the components, thereby allowing an input from the pen input device 120 to be precisely delivered to the coil included in the electromagnetic induction panel 390. According to an embodiment, the electromagnetic induction panel 390 may include an opening formed in at least a portion corresponding to the biometric sensor mounted in the electronic device 100.

The first supporting member 311 may be disposed inside the electronic device 300 to be connected with the side bezel structure 310 or integrated with the side bezel structure 310. The first supporting member 311 may be formed of, e.g., a metal and/or non-metallic material (e.g., polymer). The display 330 may be joined onto one surface of the first supporting member 311, and the printed circuit board 340 may be joined onto the opposite surface of the first supporting member 311. A processor, memory, and/or interface may be mounted on the printed circuit board 340. The processor may include one or more of, e.g., a central processing unit, an application processor, a graphic processing device, an image signal processing, a sensor hub processor, or a communication processor.

The memory may include, e.g., a volatile or non-volatile memory.

The interface may include, e.g., a high definition multimedia interface (HDMI), a universal serial bus (USB) interface, a secure digital (SD) card interface, and/or an audio interface. The interface may electrically or physically connect, e.g., the electronic device 300 with an external electronic device and may include a USB connector, an SD card/multimedia card (MMC) connector, or an audio connector.

The battery 350 may be a device for supplying power to at least one component of the electronic device 300. The battery 189 may include, e.g., a primary cell which is not rechargeable, a secondary cell which is rechargeable, or a fuel cell. At least a portion of the battery 350 may be disposed on substantially the same plane as the printed circuit board 340. The battery 350 may be integrally or detachably disposed inside the electronic device 300.

The antenna 370 may be disposed between the rear plate 380 and the battery 350. The antenna 370 may include, e.g., a near-field communication (NFC) antenna, a wireless charging antenna, and/or a magnetic secure transmission (MST) antenna. The antenna 370 may perform short-range communication with, e.g., an external device or may wirelessly transmit or receive power necessary for charging. According to an embodiment, an antenna structure may be formed by a portion or combination of the side bezel structure 310 and/or the first supporting member 311.

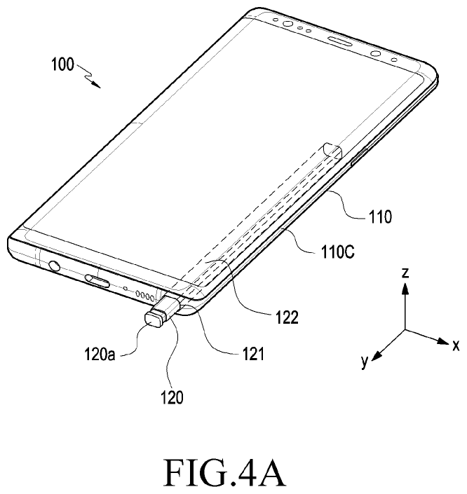

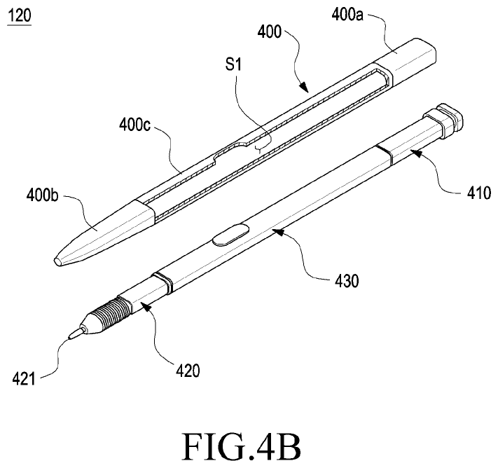

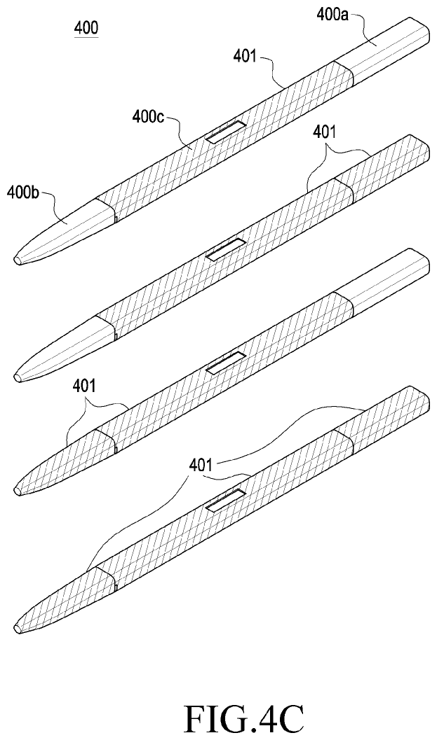

FIG. 4A is a perspective view illustrating an electronic device 100 (e.g., the electronic device 100 of FIG. 1) according to various embodiments and an example in which a portion of an input device 120 (e.g., the pen input device 120 of FIG. 1) is inserted into the electronic device 100 according to various embodiments. FIG. 4B is a perspective view illustrating an input device 120 according to various embodiments. FIG. 4C is a perspective view illustrating various examples of a housing 400 of an input device 120.

Referring to FIG. 4A, a receiving hole 121 may be formed in a portion of the housing 110 of the electronic device 100, e.g., in a portion of a side surface 110C. The electronic device 100 may include a receiving space 122 exposed to the outside through the receiving hole 121, and the pen input device 120 may be received in the electronic device 100 through the receiving space 122.

According to various embodiments, the input device 120 may include a button unit 120a on an end thereof, as a component for pulling the input device 120 out of the receiving space 122 of the electronic device 100. If the user pushes the button unit 120a, repulsive force providing elements (e.g., at least one spring) configured in association with the button unit 120a may work, allowing the input device 120 to escape from the receiving space 122.

According to various embodiments, the input device 120 may be an elongated, pen-shaped input device. Corresponding thereto, the receiving space 122 may have an elongated shape inside the electronic device 100.

According to various embodiments, the input device 120 may include antenna elements that may perform communication (e.g., Bluetooth low energy (BLE)) with the electronic device 100 when the input device 120 is received in the receiving space 122 or when the input device 120 is removed from, and positioned outside the electronic device 100.

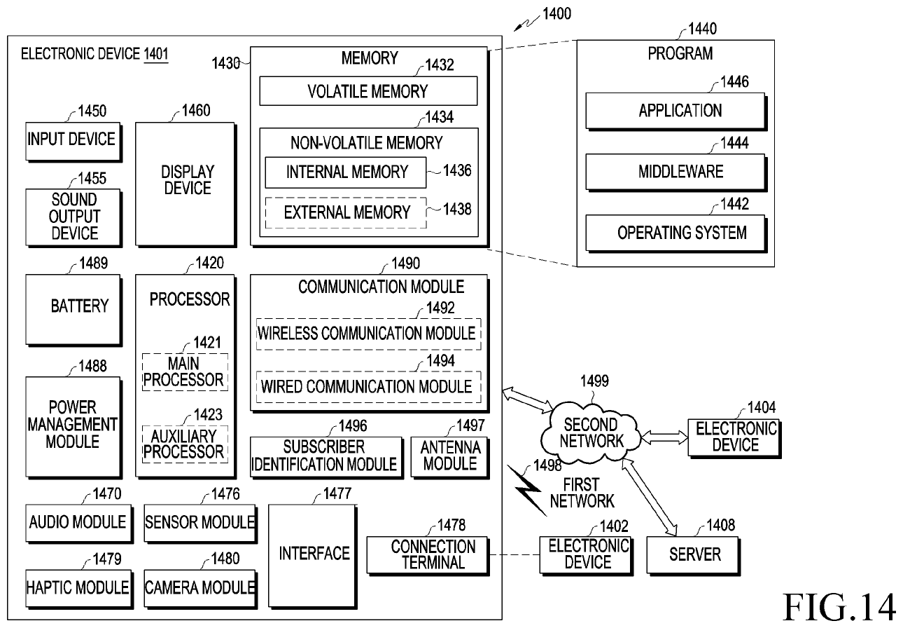

According to various embodiments, the electronic device 100 may also include a communication module capable of communicating with the input device 120. Here, the communication module may be a component including the above-described antenna (e.g., the antenna 370 of FIG. 3). According to various embodiments, the electronic device 100 may further include an electromagnetic induction panel (e.g., 390 of FIG. 3) (e.g., a digitizer) for receiving input signals from the input device 120. According to various embodiments, the electronic device 100 may further include a processor. According to an embodiment, the processor may be a component that controls the electronic device 100 and/or the input device 120 not to process the input signal received while the input device 120 is in the receiving hole 121 but to process the input signal received while the input device 120 is outside the receiving hole 121. The communication module and processor are described below in detail with reference to FIG. 14.

The configuration of the input device 120 except for the electronic device 100 is described below in detail. It should be noted that the input device 120 falls within the category of an electronic device but, for convenience of description (to distinguish it from the electronic device 100), it may be referred to as the input device.

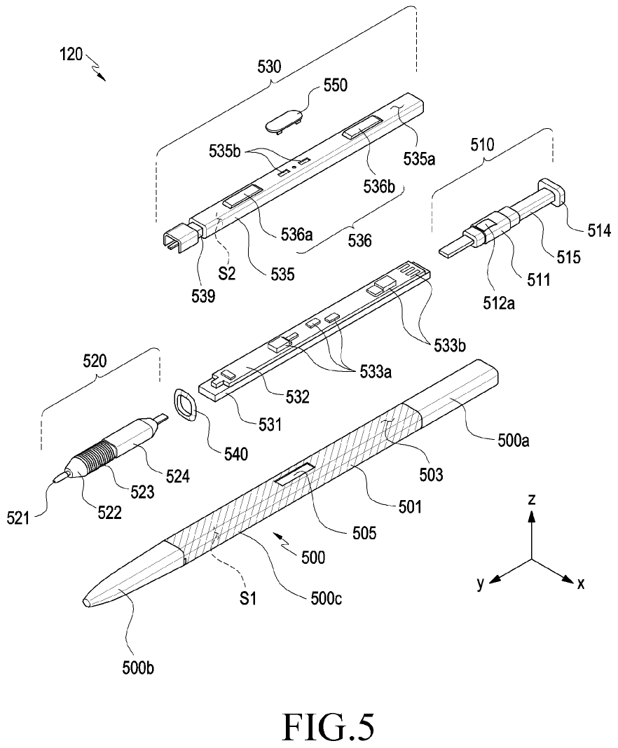

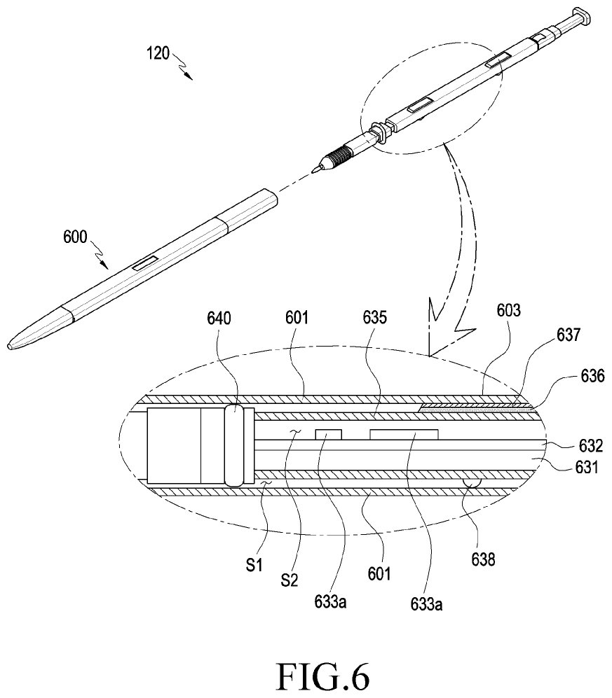

In the following embodiments, the housing (e.g., 400 of FIGS. 4B and 4C, 500 of FIG. 5, or 600 of FIG. 6) of the input device 120 may be described in detail. To avoid confusion between terms, in the above-described embodiments, the housing 110 of the electronic device 100 and the housing (e.g., 400 of FIGS. 4B and 4C, 500 of FIG. 5, or 600 of FIG. 6) of the input device 120 described below may be referred to as a ‘first housing’ (or main body part)’ and a ‘second housing,’ respectively.

Referring to FIG. 4B, the input device 120 may include a housing 400 (or a second housing) forming the outer shape of the input device 120 and an internal assembly surrounded by the housing 400. The internal assembly may be retractable from the housing 400, and may be prepared in a uni-body structure to configure the complete input device 120 by being inserted into the housing 400 by a single assembly operation. Various electronic components and circuit components may be formed in the internal assembly.

According to various embodiments, the housing 400 may have a shape that is thin and elongated as a whole. The housing 400 may include a first end 400a and a second end 400b, and a body 400c positioned between the first end 400a and the second end 400b. With the body 400c interposed therebetween, the first end 400a and the second end 400b may be positioned opposite each other. Here, the second end 400b may have a shape that becomes narrower toward the end, e.g., a pen tip shape.

According to various embodiments, the body 400c may correspond to a conductive part 401. Here, the conductive part 401 may mean that the body is formed of a metallic material, such as aluminum.

According to various embodiments of the disclosure, as the body 400c is formed of the conductive part 401, it is possible to evoke an aesthetic feeling from the user of the input device and a provide a feel of grip different from those of conventional synthetic pens.

According to various embodiments, the housing 400 of the input device 120 may include an inner space S1 at least partially surrounded by the conductive part 401. The internal assembly may be inserted and disposed in the inner space S1. According to various embodiments, the inner space S1 may extend to an inner surface of the first end 400a and/or the second end 400b to provide a wider mounting space.

According to various embodiments, the cross section of the pen housing 400 may be shaped as an ellipse with a longer axis and a shorter axis and may overall be shaped as an elliptical cylinder. The receiving space 122 of the electronic device 100 shown in FIG. 4A may also have an elliptical cross section corresponding to the shape of the pen housing 400. According to various embodiments, as the length of the short axis of the housing 400 decreases, it may be advantageous in reducing the height of the receiving space 122 and resultantly in decreasing the overall thickness of the electronic device 100 including the receiving space 122.

Referring to FIG. 4B, the internal assembly may have an overall thin, elongated shape corresponding to the shape of the housing 400. The internal assembly may largely be divided into three components along the lengthwise direction. For example, the internal assembly may include an ejection member 410 disposed in the position corresponding to the first end 400a of the housing 400, a circuit board unit 430 disposed in the position corresponding to the body 400c of the housing 400, and a coil unit 420 disposed in the position corresponding to the second end 400b of the housing 400.

According to various embodiments, with respect to a method for assembling the input device 120, the ejection member 410, the circuit board unit 430, and the coil unit 420 may be integrally formed or may be assembled by being inserted through the first end 400a-side of the housing 400 or one side of the body 400c according to a combination of various assembling methods thereof. For example, with the second end 400b connected with the body 400c, the assembly of the coil unit 420 and the circuit board unit 430 may be inserted and assembled. According to another embodiment, the input device 120 may be assembled in such a manner that the assembly of the ejection member 410, the circuit board unit 430, and the coil unit 420 is simultaneously inserted after all of the second end 400b, the body 400c, and the first end 400a are connected. According to the above-described assembly method, e.g., a portion (e.g., an inside wall of the body 400c) of the inner wall of the housing 400 may be scratched and damaged by the molding part (or mold part) or various components (e.g., a C-clip) of the assembly. In some embodiments, as a portion (e.g., the body 400c) of the housing 400 includes the conductive part 401, the contact portion between the conductive part 401 formed for a seamless communication environment and the internal assembly may be damaged in which case poor contact and corrosion by moisture may arise. Hereinafter, various embodiments for addressing such issues may be provided.

In various embodiments of the disclosure, at least a portion of the housing 400 may be formed of a metallic material (e.g., aluminum) to form the conductive part 401. Further, another part of the housing 400 may be formed of, e.g., a synthetic resin (e.g., plastic) material. If at least a portion of the housing 400 is formed of the conductive part 401, a better aesthetic and/or grip feeling may be obtained, and the housing 400 may be utilized as an antenna radiating means.

According to various embodiments, in an embodiment in which the body 400c is formed of the conductive part 401, the entire body may be formed of the conductive part 401. According to another embodiment, the outer surface of the body may be formed of a conductive part 401, and the inner surface (a portion that directly forms the inner space S1) may be formed of an insulator. According to another embodiment, the inner surface (or outer surface) of the body 400c may undergo anti-corrosion/anti-conductance treatment (e.g., painting, anodizing) to prevent corrosion and electric shocks. Other various embodiments are also applicable.

Referring to FIG. 4C, the conductive part 401 according to an embodiment may be formed only in the body 400c of the housing 400, and the other portions (the first end 400a and the second end 400b) of the housing 400 may be formed of a material (e.g., plastic) different from the conductive part 401. According to another embodiment, the conductive part 401 may be formed at the first end 400a including the body 400c. According to yet another embodiment, the conductive part 401 may also be formed at the second end 400b including the body 400c. According to yet another embodiment, the conductive part 401 may be formed over the entire area of the housing 400 including the body 400c, the first end 400a, and the second end 400b. As such, the formation of the conductive part 401 in the housing 400 may vary according to embodiments. It should be noted that the various embodiments of the disclosure are not limited to the above-described embodiments.

Referring to FIG. 5, an input device 120 may include a housing 500 including a first end 500a, a second end 500b, and a body 500c, in which at least a portion (e.g., a body 500c portion of FIG. 5) of the first end 500a, the second end 500b, and/or the body 500c includes a conductive part 501, and an ejection member 510 (e.g., the ejection member 410 of FIG. 4B), a coil unit 520 (e.g., the coil unit 420 of FIG. 4B), and a circuit board unit 530 (e.g., the circuit board unit 430 of FIG. 4B), as an internal assembly inserted into an inner space S1 of the housing 500. Further, the input device 120 may include a circuit board 532, as a component of the circuit board unit 530, and an internal structure 535.

According to various embodiments, the ejection member 510 of the internal assembly may be a component for removing the pen input device 120 from the receiving space (e.g., 122 of FIG. 4A) of the electronic device (e.g., 100 of FIG. 4A). According to an embodiment, the ejection member 510 may include a mold part 511 and a shaft 515 and a button unit 514 disposed at a rear end of the mold part 511.

If the internal assembly is fully inserted into the housing 300, the portion including the mold part 511 and the shaft 515 may be surrounded by the first end 500a of the housing 400, and the button unit 514 (e.g., 120a of FIG. 4A) may be exposed to the outside of the first end 500a. According to various embodiments, the button unit 514 may correspond to a push button providing a click feeling to the user or a button having a locking structure so that the user may remove the pen input device using her fingernail.

According to various embodiments, the ejection member 510 may be a means for generating a click mechanism. If the user presses the button unit 514, a ‘click’ may occur due to a push-pull operation, through which the input device 120 in the inserted state may be pulled out of the electronic device 100. Alternatively, the pen input device 120 may be used as a means for switching input modes (or performing a pop-up function) in the detached state from the electronic device 100. According to an embodiment, when the input device 120 is removed from the electronic device 100, the pen input device 120 may easily be pulled out from the receiving space 122 using the repulsive force of a spring (not shown) designed to operate in connection with the movement of the shaft 515 of the ejection member 510.

According to various embodiments, the coil unit 520 of the internal assembly may include a pen tip 521 that is exposed to the outside of the second end 400b if the internal assembly is fully inserted into the housing 400, a first packing ring 522 provided for waterproof and dustproof purposes, a coil 523 wound a plurality of times, and a pen pressure sensing unit 524 for acquiring a change in pressure due to pressurization of the pen tip 521. The first packing ring 522 may be formed of epoxy, rubber, urethane, or silicone. The first packing ring 522 may be provided for waterproof or dustproof purposes and protect the coil unit 520 and the circuit board unit 530 from water or dust.

In the input device 120, the coil unit 520 may be a means for generating input signals. According to various embodiments, the pen tip 521 may generate a pen coordinate signal in the form of a magnetic field and may generate a specific resonance frequency signal according to the size of the coil and the number of windings. According to various embodiments, the pen pressure sensing unit 524 may include a variable capacitor that changes capacitance in response to the pen pressure, thereby altering the resonance frequency. According to various embodiments, the user may bring the pen tip 521 into contact with the display of the electronic device 100 and implement a user input (e.g., a writing) on the electronic device 100. Here, the pen tip 521 does not necessarily have to contact the display, and a hovering input is also possible while the pen tip 521 is spaced apart from the display surface. The user input may be performed by an electromagnetic action between the electromagnetic induction panel (e.g., 390 of FIG. 3) (e.g., a digitizer) provided in the electronic device 100 and the coil unit 520.

According to various embodiments, the circuit board unit 530 may include a printed circuit board 532 and a base 531 surrounding at least one surface of the printed circuit board 532. The base 531 may serve to protect the printed circuit board 532 from a physical impact acting on the pen input device 120. According to various embodiments, a switch may be provided on the printed circuit board 532. A side button 550 provided in the pen input device 120 may be used to press the switch and may be exposed to the outside through a side opening 505 of the pen housing 500.

Referring back to FIG. 5, the circuit board unit 530 may include various electronic components and circuits. According to an embodiment, the circuit board unit 530 may be electrically connected to the coil unit 520, and according to another embodiment, in addition to being electrically connected to the coil unit 520, the circuit board unit 530 may also be connected with the ejection member 510.

In the input device 120 according to various embodiments, various electronic components 533a may be disposed on or adjacent to the printed circuit board 532. For example, a battery may be among the electronic components 533a. Furthermore, the input device 120 may further include a charging circuit for charging the battery. As the input device 120 includes a battery unit, the input device may be used as an input device 120 that performs an active function (e.g., BLE communication), but not as a mere writing tool. The battery is not limited to any specific battery. For example, as the battery, various types of batteries may be used, including a chip-type battery or a cylinder-type battery.

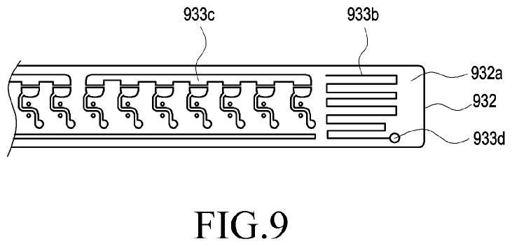

In the input device 120 according to various embodiments, the communication circuit 533b may be disposed on or adjacent to the printed circuit board 532. According to an embodiment, the communication circuit 533b may be a wireless communication circuit, through which the input device 120 may communicate with another external electronic device (e.g., 100) physically spaced apart from the input device 120. According to an embodiment, the communication circuit 553b may be manufactured in the form of an antenna module including at least one antenna radiator. According to another embodiment, the communication circuit 533b may be an antenna embedded in the printed circuit board 532 as described below with reference to FIG. 9. According to an embodiment, the communication circuit 533b may be a circuit supporting Bluetooth low energy (BLE). The communication circuit 533b receives power from the charging circuit and, when a specific voltage is reached, the communication circuit 533b may be enabled and paired with the electronic device 100 through BLE communication. According to an embodiment, a state of charge of the battery may be monitored using the communication circuit 533b and, to that end, the communication circuit 533b may periodically perform communication with the electronic device 100.

The pen input device 120 according to various embodiments of the disclosure may include an internal structure 535. According to an embodiment, the internal structure 535 may be disposed in the first inner space S1 of the housing 500. At least a portion of the internal structure 535 may be located inside the conductive part 501 of the housing 500.

According to various embodiments, the internal structure 535 may be a tube-shaped structure, forming a second inner space S2 that is elongated. The second inner space S2 may have a sufficient size to receive the printed circuit board 532. According to an embodiment, the second inner space S2 may have a sufficient size to be able to receive the printed circuit board 532, even with a base 531 for supporting at least one surface of the printed circuit board 532 disposed on one side of the printed circuit board 532 and various components (e.g., 533a and 533b) mounted on (or adjacent to) the printed circuit board 532.

A first conductive layer 536 facing the inner surface of the conductive part 501 of the housing 500 may be formed on the outer surface (e.g., the upper surface 535a of the internal structure 535) of the internal structure 535.

According to various embodiments, the wireless communication circuit 533b may be located inside the second inner space S2. Further, the wireless communication circuit 533b may be electrically connected to the first conductive layer 536 and wirelessly transmit and/or receive a signal to/from the outside (e.g., the electronic device 100) using at least a portion of the conductive part 501. Here, the first conductive layer 536 may form a contact structure for electrical connection between the conductive part 501 of the housing 500 and the communication circuit 533b. Here, the first conductive layer 536 may form an indirect contact structure with the conductive part 501 of the housing 500 through a non-conductive layer (e.g., 637 of FIG. 6 described below) disposed between the first conductive layer 536 and the conductive part 501.

According to various embodiments, the first conductive layer 536 may have a pad shape of a predetermined area or more to prevent damage to the inner surface of the housing 500 when the internal structure 535 is inserted into the housing 500. For example, the first conductive layer 536 may have a pad shape, and a length extending along the length direction of the internal structure 535 may be formed to be relatively longer than the width of the internal structure 535. According to an embodiment, the pad-shaped first conductive layer 536 forms a contact face portion facing the inner surface of the conductive part 501, and the contact face portion may be designed to remain spaced apart from the inner surface of the conductive part 501 by a predetermined distance. According to an embodiment, the contact face portion may protrude from an outer surface (e.g., 535a) of the internal structure 535. The contact face portion protruding from the outer surface (e.g., 535a) of the internal structure 535 may have a flat shape or may be formed in a structure in which the inclination or curve decreases toward the edge. In this structure, the first conductive layer 536 may be indirectly connected to the conductive part 501. Through the indirect connection between the first conductive layer 536 and the conductive part 501, the communication circuit 533b may be coupled (e.g., AC coupling) with the conductive part 501.

According to an embodiment, the first conductive layer 536 may form a waterproof structure. For example, the contact face portion of the first conductive layer 536 may protrude convexly from an outer surface (e.g., 535a) of the internal structure 535. The edge of the contact face portion may be bent toward the second inner space S2 of the internal structure 535 and may have a structure in which a gap from the internal structure 535 is minimized. Accordingly, it is possible to prevent moisture from entering through the gap between the first conductive layer 536 and the internal structure 535. According to another embodiment, when a non-conductive layer (e.g., 637 of FIG. 6 to be described below) is formed on the first conductive layer 536, the edge of the non-conductive layer is led into the inside (e.g., the second inner space S2) of the internal structure 535, minimizing the gap.

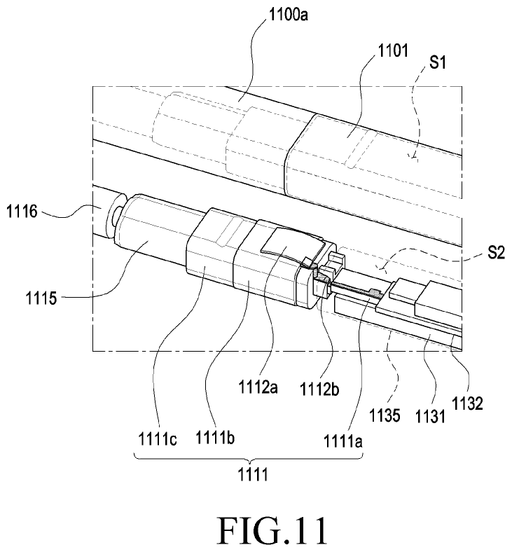

According to various embodiments, a plurality of first conductive layers 536 may be provided on the surface (e.g., 535a) of the internal structure 535. According to an embodiment, the first conductive layer 536 may include a first conductive plate 536a and a second conductive plate 536b. Here, the first conductive plate 536a and the second conductive plate 536b may be connected to different components (or circuits) mounted on the printed circuit board. For example, the first conductive plate 536a may be electrically connected to the power supply part of the communication circuit 533b, and the second conductive plate 536b may be electrically connected to the ground unit of the communication circuit 533b. Although two first conductive layers 536a and 536b are illustrated in FIG. 5, various embodiments of the disclosure are not necessarily limited thereto. Other various numbers of first conductive layers 536a and 536b may be provided. For reference, another conductive layer 1112a is illustrated in FIG. 11 to be described below, and may perform functions similar to those of the first conductive layers 536a and 536b.

As illustrated in FIG. 5, the plurality of first conductive layers 536 may be shaped to be exposed to an upper surface (e.g., 535a) of the internal structure 535. According to an embodiment, the first conductive plate 536a may be formed on an upper surface (e.g., 535a) of the internal structure 535 to be spaced apart from the second conductive plate 536b by a predetermined distance. Although not illustrated in the drawings, the plurality of first conductive layers 536 may be individually and electrically connected to a plurality of conductive lines extending through the printed circuit board. As described below in detail, the plurality of first conductive layers 536 may be connected to the antenna module through the conductive lines, may be coupled (e.g., AC coupling) to the conductive part 501, and may use the conductive part 501 as a radiator.

According to various embodiments, a first coupling part 535b for mounting the side button 550 may be formed on the surface of the internal structure 535. Further, a second coupling part 539 for mounting a waterproof sealant (or second packing ring) 540 may be formed on one side of the internal structure 535. It should be noted that although FIG. 5 illustrates an example in which the coupling parts 535b and 539 are formed only on one side of the internal structure 535, embodiments of the disclosure are not limited thereto. According to another embodiment, e.g., the waterproof sealant 540 is mounted not only on the second coupling part 539 formed on the front end of the internal structure 535, but also on another coupling part (not illustrated) in the internal structure 535, and a solid waterproof structure may thus be formed. For example, in the embodiment of FIG. 5, it is shown that the waterproof sealant 540 is mounted on the second coupling part 539 on the front side of the internal structure 535. According to another embodiment, the waterproof sealant 540 may be mounted on the rear side of the internal structure 535 as well.

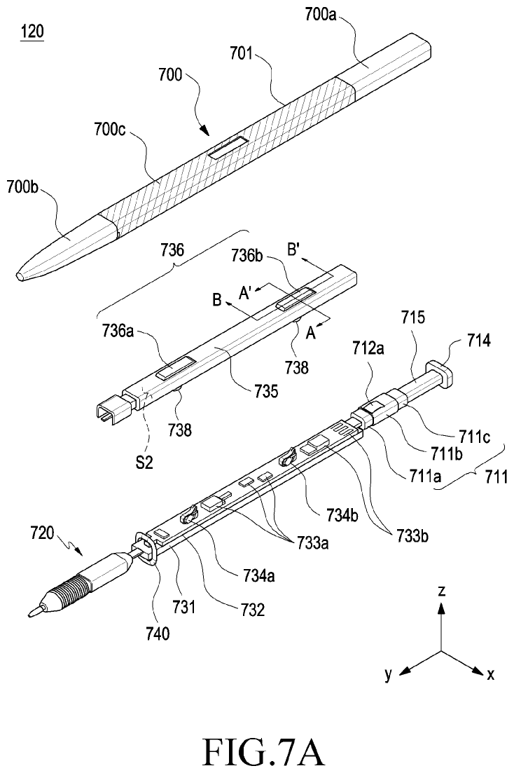

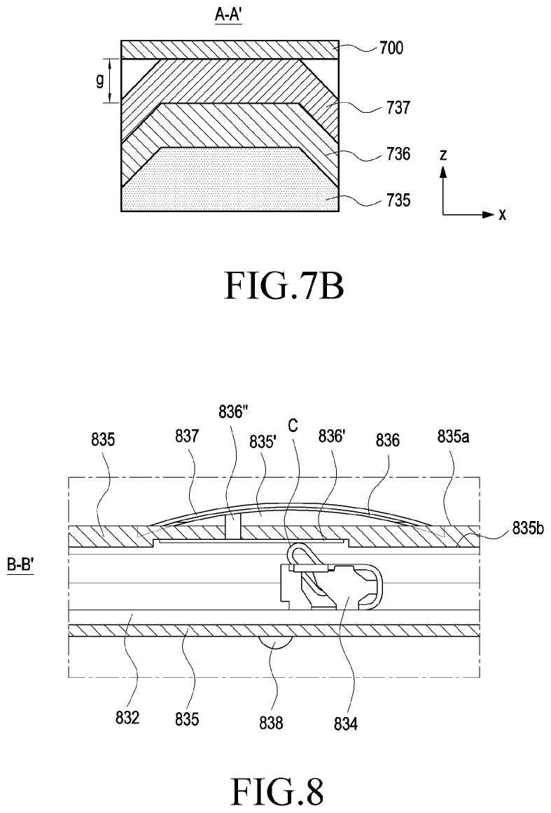

FIG. 6 is a cross-sectional view illustrating a portion of an input device 120 according to various embodiments. FIG. 7A is a perspective view illustrating an input device 120 according to an embodiment different from that of FIG. 5. FIG. 7B is a cross-sectional view illustrating the first conductive layer 736 of FIG. 7A according to various embodiments. For reference, FIG. 7B may be a cross-sectional view illustrating the internal structure 735 of FIG. 7A, taken along line A-A′.

First, referring to FIG. 6, in an input device 120 according to various embodiments of the disclosure, an internal assembly may be assembled in an elongated housing 600. Conventionally, the inner surface of the housing 600 may be scratched by the mold part (e.g., the mold part 511 of FIG. 5 or the mold part 711 of FIG. 7A) of the internal structure or electronic components while inserting the internal assembly into the elongated housing 600. However, in various embodiments of the disclosure, various components of the internal assembly including a base 631, a printed circuit board 632, and various electronic components 633a may be received in an inner space S2 of the internal structure 635, and the internal structure 635 may be assembled in the housing 600 in the form surrounding the internal assembly. As a result, in the input device 120 according to various embodiments of the disclosure, the likelihood that the inner surface of the housing 600 is scratched may be significantly reduced compared to the prior art.

Further, in the case where the housing 600 is formed of, e.g., metal, the risk of scratching the inner surface of the housing 600 may be further reduced by forming the first conductive layer 636, which is prepared to enhance the antenna radiation performance, a component exposed to the surface of the internal structure 635, in the shape of a pad with a predetermined area. According to the embodiment illustrated in FIG. 6, at least a portion of the housing 600 is composed of a conductive part 601, and the internal structure 635 is mounted thereon. According to an embodiment, when the internal structure 635 is mounted in the first inner space S1 of the housing 600, a waterproof sealant 640 comes substantially in tight contact with the conductive part 601, restricting the movement of the moisture introduced in the first inner space S1.

Referring to FIGS. 6 to 7B together, an input device (e.g., 120 of FIG. 5) according to various embodiments of the disclosure may include a non-conductive layer 637 or 737 between a first conductive layer 636 or 736 and the inner surface of the conductive part 601 or 701 of the housing 600 or 700.

The non-conductive layer 637 or 737 is positioned between the first conductive layer 636 or 736 and the housing 600 or 700, indirectly connecting the first conductive layer 636 or 736 and the conductive part 601 or 701. Here, the non-conductive layer 637 or 737 may serve as a space-holder to form uniform capacitance between the first conductive layer 636 or 736 and the conductive part 601 or 701. The capacitance may be, e.g., 5 pF or more to meet a frequency band required for BLE communication. To form a uniform capacitance, the non-conductive layer 637 or 737 may serve to maintain a predetermined gap g between the first conductive layer 636 or 736 and the conductive part 601 or 701. When the assembly of the input device 120 is complete, the non-conductive layer 637 or 737 is brought substantially in tight contact with the housing 600 or 700, so that the distance between the non-conductive layer 637 or 737 and the inner surface of the housing 600 or 700 may converge to zero. Accordingly, the predetermined gap g between the first conductive layer 636 or 736 and the conductive part 601 or 701 may be kept constant.

According to various embodiments, the non-conductive layer 637 or 737 may be firmly attached to the upper surface of the first conductive layer 636 or 736 and may have a shape similar to the shape of the first conductive layer 636 or 736. For example, as in the cross section illustrated in FIG. 7B, if both edges of the first conductive layer 736 are shaped to be bent toward the surface of the internal structure, both edges of the non-conductive layer 737 may also be shaped to be bent toward the surface of the internal structure.

According to an embodiment, the input device 120 may further include an elastic member 638 or 738 that is positioned to face the inner surface of the conductive part 601 or 701 of the housing 600 or 700 and to pressurize the internal structure 635 or 735. The elastic member 638 or 738 allows the distance between the non-conductive layer 637 or 737 and the housing 600 or 700 to converge to zero, thereby maintaining a designated capacitance. According to an embodiment, the elastic member 638 or 738 may be shaped to protrude outward from the outer surface of the internal structure 635 or 735. For example, if the first conductive layer 636 or 736 and the non-conductive layer 637 or 737 are formed to face in the same direction as the upper surface 603 of the housing 600 from the upper surface of the internal structure, the elastic member 638 or 738 may protrude from the lower surface on the opposite side. The elastic member 638 or 738 may be formed on the opposite side of where the first conductive layer 636 or 736 and the non-conductive layer 637 or 737 are formed and may support the internal structure 635 or 735 as a reaction to the tight contact to the housing 600.

According to various embodiments, the elastic member 638 or 738 may be formed of a material (e.g., synthetic resin, rubber, or sponge) that applies elastic force to allow the gap to turn back to its original state although the gap between the first conductive layer 636 or 736 and the conductive part 601 and 701 is changed by the external force exerted to the input device 120. Or, the elastic member 638 or 738 may have a structure that may be restored to its original state (e.g., a chamfer structure or a leaf spring structure).

According to various embodiments, the elastic member 638 or 738 may be formed of a material (or a more flexible material) that may be pressed more than the non-conductive layer 637 or 737. As the elastic member 638 or 738 absorbs impacts, the impacts applied to the first conductive layer 636 or 736 may be reduced. Accordingly, the overall durability of the input device 120 may be enhanced.

FIG. 8 is a cross-sectional view illustrating a second conductive layer 836′, a conductive via 836″, and a flexible conductive member 834 of an input device (e.g., 120 of FIG. 7A) according to various embodiments.

Referring to FIGS. 7A and 8 together, an input device (e.g., 120 of FIG. 7A) according to various embodiments may further include a flexible conductive member 734 or 834. The flexible conductive member 734 or 834 may be a component for connecting the wireless communication circuit (e.g., 733b) mounted on the printed circuit board 732 or 832 with the first conductive layer 736 or 836. Here, the ‘connection’ may include a physical connection and an electrical connection. The flexible conductive member 734 or 834 has a predetermined height and forms a clip (e.g., C-clip) structure at an end thereof, thereby forming a contact with the inner surface (e.g., 835b) of the internal structure 735 or 835. As the end of the flexible conductive member 734 or 834 may be flexibly or elastically moved during use, it may maintain a secure electrical connection between the first conductive layer 736 or 836 and the wireless communication circuit (e.g., 733b) although an external force is applied to the input device 120.

According to various embodiments, the flexible conductive member 734 or 834 may be disposed on the upper surface of the printed circuit board 732 or 832. According to one embodiment, one flexible conductive member 734 or 834 may be used, but according to another embodiment, a plurality of flexible conductive members 734 or 834 may be used.

According to an embodiment, there may be provided the same number of flexible conductive members 734 or 834 as the number of first conductive layers 736 or 836. For example, if there are provided two first conductive layers 736 or 836 (e.g., a first conductive plate 736a and a second conductive plate 736b), there may be provided two flexible conductive members 734 or 834 (e.g., 734a and 734b).

As described above through the embodiment of FIG. 6, the first conductive layer may protrude outward from the outer surface (e.g., 835a) of the internal structure 835 and may have a curved shape as viewed in cross section. According to one embodiment, a space may be formed between the first conductive layer 836 and the internal structure 835, but according to another embodiment, a portion 835′ protruding from the internal structure 835 below the first conductive layer 836 may be formed to support the first conductive layer 836.

The input device (e.g., 120 of FIG. 7A) according to various embodiments of the disclosure may further include a second conductive layer (e.g., 836′) formed in the second inner space S2 of the internal structure 735 or 835 and electrically connected with the first conductive layer 736 or 836.

According to an embodiment, the second conductive layer (e.g., 836′) may be disposed on the inner surface of the internal structure 735 or 835. When the first conductive layer 836 is formed on the outer surface of the internal structure 735 or 835, the second conductive layer (e.g., 836′) may be disposed on the opposite side of where the first conductive layer 836 is formed on the inner surface of the internal structure 735 or 835.

According to various embodiments, the second conductive layer (e.g., 836′) may also have a shape (e.g., a pad) similar to the first conductive layer 836. However, unlike the first conductive layer 836, the second conductive layer 836′ is formed in the second inner space S2 of the internal structure 735 or 835, so that there is no need to form a waterproof structure, and the second conductive layer 836′ may have a flat shape, not a curved shape, when viewed at cross-sectional view.

Referring to FIG. 8, the second conductive layer 836′ may be a portion that directly contacts the flexible conductive member 734 or 834. Further, the internal structure 835 of the input device (e.g., 120 of FIG. 7A) may further include a conductive via 836″ having one end connected to the second conductive layer 836′. The other end of the conductive via 836″ may be connected to the first conductive layer 836, and accordingly, the first conductive layer 836 and the second conductive layer 836″ may be electrically connected to each other. Here, the conductive via (e.g., 836″) may pass through the internal structure 835. According to an embodiment, two or more conductive vias (e.g., 836″) may be formed.

By using the conductive via 836″, conductive layers (e.g., the first conductive layer 836 and the second conductive layer 836′) disposed at different heights may be interconnected, and a conductive part (e.g., 701 of FIG. 7A) positioned outside (e.g., the first inner space S1) of the internal structure 835 and the wireless communication circuit (e.g., 733b of FIG. 7A) positioned inside (e.g., the second inner space S2) of the internal structure 835 may be electrically connected with each other.

According to various embodiments of the disclosure, the wireless communication circuit (e.g., 733b of FIG. 7A) may be electrically connected with the first conductive layer 736 or 836 using the flexible conductive member 734 or 834, the second conductive layer 836′, and the conductive via 836″. In other words, the wireless communication circuit (e.g., 733b of FIG. 7A) may be connected to the first conductive layer 736 or 836 via the flexible conductive member 734 or 834, the second conductive layer 836′, and the conductive via 836″ and, after assembly, may always maintain the conductive path so that a constant magnitude of current may flow (e.g., DC input). In contrast, the first conductive layer 736 or 836 and the conductive part 701 may be spaced apart from each other physically and electrically. Instead, the first conductive layer 736 or 836 and the conductive part 701 may exhibit electrical interaction (e.g., AC coupling), and through this, the conductive part 701 may be utilized as an antenna radiator capable of generating a designated frequency of radiation.

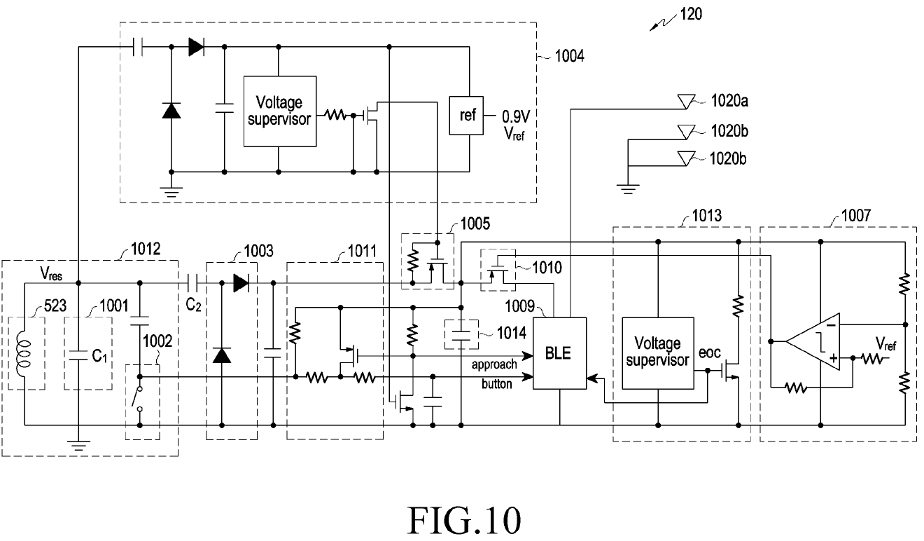

FIG. 9 is a view illustrating a wireless communication circuit 933b of an input device (e.g., 120 of FIG. 7A) according to various embodiments. FIG. 10 is a view illustrating a circuit structure of an input device (e.g., 120 of FIG. 7A) according to various embodiments.

Referring to FIG. 9, a wireless communication circuit 933b according to various embodiments may be embedded in a printed circuit board 932 (e.g., 532 of FIG. 5, 632 of FIG. 6, 732 of FIG. 7A, or 832 of FIG. 8). According to various embodiments of the disclosure, the wireless communication circuit 933b of the input device 120 includes a pattern-printed antenna (PCB Embedded Antenna, hereinafter referred to as a ‘PEA’) on the printed circuit board 932. According to this, a circuit electrically connected to the coil unit 520 may be configured in an area (not shown) of the printed circuit board 932, and a PEA pattern-printed to have a predetermined resonance frequency (e.g., 2.4 Ghz) may be configured in another area of the printed circuit board 932.

The printed circuit board 932 according to various embodiments has a first surface 932a facing in a first direction and a second surface (not shown) facing in a direction opposite to the first direction, and may include a plurality of layers formed between the first surface 932a and the second surface. Various circuits (e.g., a variable capacitor circuit) 933c and conductive patterns (e.g., 933b) for generating a predetermined resonance frequency (e.g., 2.4 Ghz) may be formed on the plurality of layers. The length or area of the conductive patterns may vary according to a designated resonance frequency value (e.g., 2.4 Ghz, 3 Ghz, . . . ) optimized for a specific input device. The printed circuit board 932 may be provided with a conductive via 933d that is formed to penetrates the plurality of layers. According to various embodiments, the plurality of layers may connect the antennas on the layers disposed at different heights through the conductive via 933d and may electrically connect components and circuits that perform different functions.

Referring to FIG. 10, according to various embodiments, an input device 120 may include at least one of a coil 523, a variable capacitor circuit 1001, a button switch 1002, a rectifier 1003, a first voltage detector 1004, a charging switch 1005, a battery 1014, a second voltage detector 1007, a short-range communication controller 1009 (BLE) (e.g., a wireless communication circuit (e.g., 733b of FIG. 7A), a booting switch 1010, or an OR gate 1011.

According to an embodiment, the coil 523 may be connected to be able to operate with the variable capacitor circuit 1001. According to an embodiment, the coil 523 may transfer a current (e.g., a detection signal or a current for charging the input device 120) by mutual induction with the electronic device (e.g., 100 of FIG. 1) to the variable capacitor circuit 1001.

According to an embodiment, the variable capacitor circuit 1001 may be a circuit which may have a variable capacitance and may include at least one of, e.g., one or more capacitors, one or more transistors, one or more input/output ports, or logic circuits.

According to an embodiment, the button switch 1002 may be connected to be able to operate with at least one of the rectifier 1003 or the OR gate 1011. According to an embodiment, the button switch 1002 may be shorted or open as the button (e.g., the side button 550 of FIG. 5) provided in the input device 120 is pressed or touched. When the button switch 1002 is shorted as the button (e.g., the side button 550 of FIG. 5) is pressed, the node connected with the capacitor C2 and the OR gate 1011 may be grounded and, when the button switch 1002 is open as the pressing of the button (e.g., the side button 550 of FIG. 5) is released, the capacitor C2 may be connected in series with the OR gate 1011. This may lead to a difference in the resonance frequency of the resonance circuit 1012 formed by the coil 523 and the connected capacitors between when the button (e.g., the side button 550 of FIG. 5) is pressed and when the button (e.g., the side button 550 of FIG. 5) is not pressed. According to an embodiment, the electronic device 101 may identify whether the button (e.g., the side button 550 of FIG. 5) of the input device 220 is pressed or not by identifying the frequency of the signal generated from the resonance circuit 1012 of the input device 120.

According to an embodiment, the rectifier 1003 may be connected to be able to operate with at least one of the button switch 1002, the first voltage detector 1004, or the charging switch 1005. According to an embodiment, the rectifier 1003 may rectify alternating current (AC) power received from the electronic device (e.g., the electronic device 100 of FIG. 1) and output from the coil 523 into DC power and transfer the DC power to at least one of the first voltage detector 1004 or the charging switch 1005.

According to an embodiment, the first voltage detector 1004 may be connected to be able to operate with at least one of the rectifier 1003, the charging switch 1005, the short-range communication controller 1009, or the OR gate 1011. According to an embodiment, the first voltage detector 1004 may detect a voltage value on the path connecting the rectifier 1003 and the short-range communication controller 1009. According to an embodiment, the first voltage detector 1004 may detect whether the magnitude of the detected voltage belongs to a designated range based on the magnitude of the detected voltage value. According to an embodiment, the designated range may be divided into a range, e.g., from 1.5V to 3.5V (level 1 range) or a range not less than 3.5V (level 2 range) but this is merely an example. For example, when the magnitude of the detected voltage belongs to level 2 range, the input device 120 may be in the state of having been inserted into the receiving space (e.g., the receiving space 122 of FIG. 4A) of the electronic device (e.g., the electronic device 100 of FIG. 1) and, when the magnitude of the detected voltage belongs to level 1 range, the input device 120 may be in the state of being used over (touching) the display (e.g., 101 of FIG. 1) of the electronic device (e.g., the electronic device 100 of FIG. 1) by the user. According to an embodiment, when the magnitude of the detected voltage belongs to level 2 range, the first voltage detector 1004 may apply an enable signal to the charging switch 1005 to turn on the charging switch 1005 to allow the charging signal transmitted from the rectifier 1003 to be applied to the battery 1014. According to an embodiment, when the magnitude of the detected voltage belongs to level 1 range, the first voltage detector 1004 may control the charging switch 1005 to turn, or remain, off. According to an embodiment, the first voltage detector 1004 may transfer the DC power from the rectifier 1003 to the charging switch 1005.

According to an embodiment, when the magnitude of the detected voltage belongs to level 2 range, the first voltage detector 1004 may apply an enable signal to the short-range communication controller 1009. In this case, the short-range communication controller 1009 may transmit a wireless signal (e.g., an advertising signal or message) to the short-range communication controller (e.g., a communication module) of the electronic device (e.g., the electronic device 100 of FIG. 1). According to an embodiment, when the magnitude of the detected voltage belongs to level 1 range, the first voltage detector 1004 may not apply an enable signal to the short-range communication controller 1009. The enable signal may be, or may not necessarily be, of the same type as the enable signal that the first voltage detector 1004 applies to the charging switch 1005.

According to an embodiment, the first voltage detector 1004 may include a conductive line between the first voltage detector 1004 and the short-range communication controller 1009 to transmit, to the short-range communication controller 1009, a signal related to the above-described state of the input device 120 (e.g., the state of having been inserted into the receiving space (e.g., 122 of FIG. 4A) of the electronic device 100 of FIG. 1 or touching the display (e.g., 101 of FIG. 1) of the electronic device (e.g., the electronic device 100 of FIG. 1) by the user). According to another embodiment, the charging switch 1005 may be connected via the conductive line with the short-range communication controller 1009 and, when the charging switch 1005 turns on, transfer the enable signal from the first voltage detector 1004 to the short-range communication controller 1009.

According to an embodiment, the charging switch 1005 may be connected to be able to operate with the rectifier 1003, the first voltage detector 1004, the battery 1014, the second voltage detector 1007, and the short-range communication controller 1009. According to an embodiment, the charging switch 1005 may be turned on (e.g., shorted) or off (e.g., open) based on the strength of the voltage detected by the first voltage detector 1004. According to an embodiment, when the charging switch 1005 is turned on, the DC power transferred from the rectifier 1003 or the first voltage detector 1004 may be applied to the battery 1014 or the second voltage detector 1007. In this case, according to an embodiment, the short-range communication controller 1009 may identify that the input device 120 is in the state of being charged by the electronic device (e.g., 100 of FIG. 1). According to an embodiment, when the charging switch 1005 is turned off, the DC power transferred from the rectifier 1003 or the first voltage detector 1004 may not be applied to the battery 1014 or the second voltage detector 1007. In this case, according to an embodiment, the short-range communication controller 1009 may identify that the input device 120 is in the state of being not charged by the electronic device (e.g., 100 of FIG. 1). Here, the state in which the input device 120 is not being charged may mean a state in which the input device 120 is not inserted into the receiving space (e.g., 122 of FIG. 4A) of the electronic device (e.g., 100 of FIG. 1) so that it does not receive AC power from the electronic device (e.g., the coil 523).

According to an embodiment, the second voltage detector 1007 may be connected to be able to operate with at least one of the charging switch 1005, the battery 1014, or the booting switch 1010. According to an embodiment, the second voltage detector 1007 may detect a voltage value output from the battery 1014. According to an embodiment, the booting switch 1010 may be shorted based on the magnitude of the voltage value detected by the second voltage detector 1007. In this case, the short-range communication controller 1009 may be booted. As used herein, “booting” may mean cold booting which is performed when the voltage value detected by the second voltage detector 1007 is not less than a designated value (e.g., 2.4V).

The short-range communication controller 1009 according to various embodiments may establish a connection between the electronic device (e.g., 100 of FIG. 1) and a short-range communication (e.g., BLE). According to an embodiment, the short-range communication controller 1009 may perform pairing with the electronic device (e.g., 100 of FIG. 1) using a short-range wireless communication scheme, e.g., BLE. According to an embodiment, the short-range communication controller 1009 may transmit state information about the battery 1014 to the paired electronic device (e.g., 100 of FIG. 1). According to an embodiment, the short-range communication controller 1009 may exchange, with the paired electronic device (e.g., 101 of FIG. 1), signals to control at least one component included in the input device 120 or the electronic device (e.g., 101 of FIG. 1).

According to an embodiment, the OR gate 1011 may generate a signal to disregard the button (e.g., 550 of FIG. 5) input made by the user or a signal (e.g., a signal to execute an application on the electronic device) to short-range communication based on the voltage value detected by the first voltage detector 1004 and transmit the signal to the short-range communication controller 1009.

The input device 120 according to various embodiments may include a resonance circuit 1012, an overvoltage protection (OVP) circuit 1013, and an electric double layer capacitor (EDLC) (battery) 1014.

According to an embodiment, the resonance circuit 1012 may be connected to be able to operate with the rectifier 1003. According to an embodiment, the resonance circuit 1012 may include a coil (e.g., the coil 523 of FIG. 5), a variable capacitor circuit 1001, and a button switch 1002.

According to an embodiment, the OVP circuit 1013 may detect the strength (e.g., 2.6V) of the voltage applied to the EDLC 1014 and limit application of a voltage not less than a predesignated strength to the EDLC 1014.

According to an embodiment, the resonance circuit 1012, the first voltage detector 1004, the charging switch 1005, the OVP circuit 1013, the second voltage detector 1007, the booting switch 1010, and the OR gate 1011 may together form a single integrated circuit or may, together with the EDLC 1014 and the short-range communication controller 1009, form a single integrated circuit.

Referring back to FIG. 10, the short-range communication controller 1009 may be electrically connected to at least one conductive path for antenna radiation. Here, at least one conductive path may include a plurality of conductive layers 1020a and 1020b (e.g., the first conductive layer 736 of FIG. 7A). The plurality of conductive layers 1020a and 1020b may include a conductive plate 1020a (e.g., the first conductive plate 736a of FIG. 7A) connected to a power supply unit and a conductive plate 1020b (e.g., the second conductive plate 736b of FIG. 7A) connected to a ground unit.

According to an embodiment, the conductive layers 1020a and 1020b of FIG. 10 may mean first conductive layers 736a and 736b formed on an outer surface of an internal structure (e.g., 735 of FIG. 7A). However, without limitations thereto, the conductive layers 1020a and 1020b of FIG. 10 may mean a third conductive layer (1112a of FIG. 11 described below) formed on the mold part (e.g., 511 of FIG. 5) of the ejection member (e.g., 510 of FIG. 5), not in the internal structure (e.g., 735 of FIG. 7A).

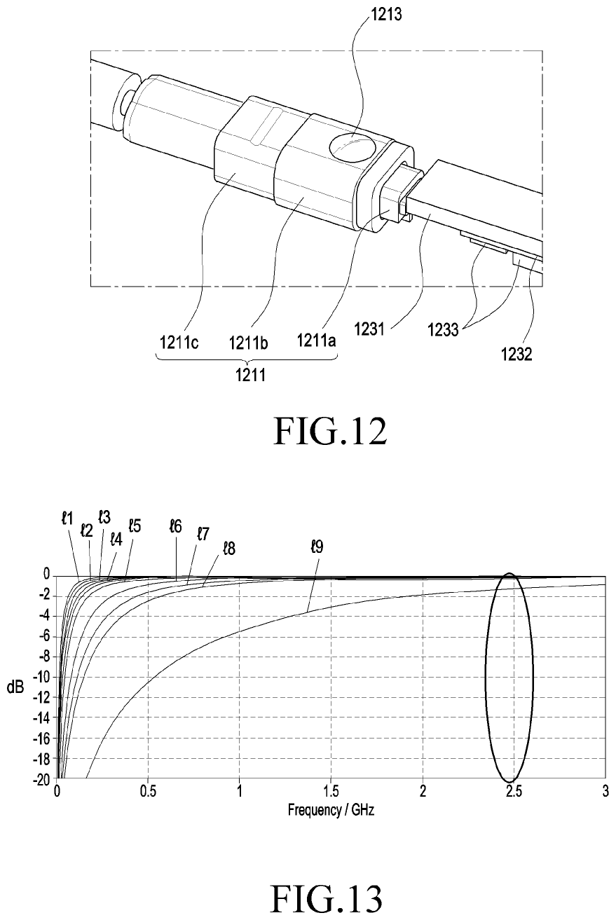

FIG. 11 is a view illustrating 1111 and a third conductive layer 1112a of an input device (e.g., 120 of FIG. 5) according to various embodiments. FIG. 12 is a view illustrating an example in which an elastic member 1213 is formed in a mold part 1211 of an input device (e.g., 120 of FIG. 5) according to various embodiments.

According to various embodiments of the disclosure, there may be provided a mold part 1111 that is elongated, has at least a portion (e.g., 1111b and 1111c) positioned inside the first end 1100a (e.g., 500a of FIG. 5) of the housing (e.g., 500 of FIG. 5) and disposed adjacent to the printed circuit board 1132. Another portion (e.g., 1111a) of the mold part 1111 may be inserted into the first inner space S1 of the conductive part 1101 (e.g., 501 of FIG. 5) of the housing and disposed adjacent to the printed circuit board 1132 on the base 1131. However, without limitations thereto, the entire mold part 1111 including the other portion (e.g., 1111a) of the mold part 1111 may be disposed at the first end 1100a, and other various embodiments may be applied. According to various embodiments, the mold part 1111 may be connected to the shaft part 1115 and the button unit 1116 forming a click mechanism on one side and may be connected to the base 1131 and or a printed circuit board 1132 on the other side. A portion (e.g., 1111a) of the mold part 1111 may be electrically connected by being inserted into the second inner space S2 of the internal structure 1135 and connected to the printed circuit board 1132.

A third conductive layer 1112a may be formed on at least a portion of the surface of the mold part 1111. The third conductive layer 1112a has substantially the same configuration as the first conductive layer (e.g., 536 of FIG. 5) but may differ from the first conductive layer (e.g., 535 of FIG. 5) in that it is formed on the surface of the mold part 1111 rather than the internal structure (e.g., 535 of FIG. 5). Here, the third conductive layer 1112a has substantially the same configuration as the first conductive layer (e.g., 536 of FIG. 5) may mean that the shape of the third conductive layer 1112a has the same configuration as the first conductive layer (e.g., 536 of FIG. 5). According to an embodiment, the third conductive layer 1112a may be electrically connected with a wireless communication circuit (e.g., 533b of FIG. 5) formed on the printed circuit board 1132 through a conductive line 1112b extending to the printed circuit board 1132. Here, the conductive line 1112b may be formed through a double injection process with a portion (e.g., 1111a) of the mold part 1111.

According to various embodiments, the third conductive layer 1112a may be a portion formed separately or alternatively to the first conductive layer (e.g., 536 of FIG. 5). By providing the third conductive layer 1112a, it is possible to form an antenna radiation structure capable of forming a designated resonance frequency regardless of the spatial limitations to the installation environment according to the size and length of the input device (e.g., 120 of FIG. 5). According to an embodiment, as illustrated in FIG. 5, two first conductive layers 536a and 536b (e.g., 536 of FIG. 5) are formed, and one third conductive layer 1112a is formed, so that three conductive layers for seamless communication with the electronic device (e.g., 100 of FIG. 1) may be formed. Here, one (e.g., the first conductive plate 536a) of the first conductive layers may be connected to the power supply unit, and the other (e.g., the second conductive plate 536b) of the first conductive layers and the third conductive layer 1112a may be connected to the ground unit. Electrical stability may be secured by allowing the number of conductive layers connected to the ground unit to be larger than the number of conductive layers connected to the power supply unit.

According to an embodiment, a non-conductive layer (not shown) may be attached to the upper surface of the third conductive layer 1112a. Accordingly, the third conductive layer 1112a may also maintain a predetermined distance from the inner surface of the housing (e.g., 500 of FIG. 5).

Referring to FIG. 12, an elastic member 1213 may be formed on a partial surface of the mold part 1211. According to an embodiment, the elastic member 1213 may be positioned on the opposite side of the third conductive layer (e.g., 1112a of FIG. 11) and support the mold part 1211, allowing the third conductive layer (e.g., 1112a of FIG. 11) to come in tight contact with the housing (e.g., 500 of FIG. 5).

According to an embodiment, the third conductive layer (e.g., 1112a) and the non-conductive layer (not shown) formed on the upper surface of the third conductive layer (e.g., 1112a of FIG. 11) may be formed on one surface of the mold part 1211, and the elastic member 1213 may be formed on the surface opposite to the surface of the mold part 1211. This structure renders it possible to absorb the impact applied to the input device (e.g., FIG. 120 of FIG. 5) and maintain a gap between the third conductive layer (e.g., 1112a of FIG. 11) and the housing (e.g., 500 of FIG. 5).

FIG. 13 illustrate graphs for antenna radiation performance indexes of an input device (e.g., 120 of FIG. 5) according to various embodiments. FIG. 13 may show a frequency band covering range of an input device for wireless communication under various capacitance conditions. Referring to FIG. 13, [symbol] 1 is a graph when the input device forms a capacitance of 33 pF, [symbol] 2 is a graph when the capacitance is 27 pF, [symbol] 3 is a graph when the capacitance is 22 pF, [symbol] 4 is a graph when the capacitance is 18 pF, [symbol] 5 is a graph when the capacitance is 15 pF, [symbol] 6 is a graph when the capacitance is 12 pF, [symbol] 7 is a graph when the capacitance is 7 pF, [symbol] 8 is a graph when the capacitance is 5 pF, [symbol] 9 is a graph when the capacitance is 3 pF, and [symbol] 10 is a graph when the capacitance is 1 pF. The input device (e.g., 120 of FIG. 5) of the present invention may include a metal housing and an internal structure inserted into the housing. In configuring such an input device (e.g., 120 of FIG. 5), it may be identified that a frequency band of 2.4 Ghz or more may be secured in a capacitance range of 3 pF or more as illustrated in FIG. 13.

FIG. 14 is a block diagram illustrating an electronic device in a network environment according to various embodiments.

Referring to FIG. 14, an electronic device 1401 (e.g., the electronic device 100 of FIG. 1) in the network environment 1400 may communicate with an electronic device 1402 (e.g., the input device 120 of FIG. 5) via a first network 1498 (e.g., a short-range wireless communication network), or an electronic device 1404 or a server 1408 via a second network 1499 (e.g., a long-range wireless communication network). According to an embodiment, the electronic device 1401 may communicate with the electronic device 1404 via the server 1408. According to an embodiment, the electronic device 1401 may include a processor 1420, memory 1430, an input device 1450, a sound output device 1455, a display device 1460, an audio module 1470, a sensor module 1476, an interface 1477, a haptic module 1479, a camera module 1480, a power management module 1488, a battery 1489, a communication module 1490, a subscriber identification module (SIM) 1496, or an antenna module 1497. In some embodiments, at least one (e.g., the display device 1460 or the camera module 1480) of the components may be omitted from the electronic device 1401, or one or more other components may be added in the electronic device 101. In some embodiments, some of the components may be implemented as single integrated circuitry. For example, the sensor module 1476 (e.g., a fingerprint sensor, an iris sensor, or an illuminance sensor) may be implemented as embedded in the display device 1460 (e.g., a display).

The processor 1420 may execute, for example, software (e.g., a program 1440) to control at least one other component (e.g., a hardware or software component) of the electronic device 1401 coupled with the processor 1420, and may perform various data processing or computation. According to one embodiment, as at least part of the data processing or computation, the processor 1420 may load a command or data received from another component (e.g., the sensor module 1476 or the communication module 1490) in volatile memory 1432, process the command or the data stored in the volatile memory 1432, and store resulting data in non-volatile memory 1434. According to an embodiment, the processor 1420 may include a main processor 1421 (e.g., a central processing unit (CPU) or an application processor (AP)), and an auxiliary processor 1423 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 1423 may be adapted to consume less power than the main processor 1421, or to be specific to a specified function. The auxiliary processor 1423 may be implemented as separate from, or as part of the main processor 1421.

The auxiliary processor 1423 may control at least some of functions or states related to at least one component (e.g., the display device 1460, the sensor module 1476, or the communication module 1490) among the components of the electronic device 1401, instead of the main processor 1421 while the main processor 1421 is in an inactive (e.g., sleep) state, or together with the main processor 1421 while the main processor 1421 is in an active state (e.g., executing an application). According to an embodiment, the auxiliary processor 1423 (e.g., an image signal processor or a communication processor) may be implemented as part of another component (e.g., the camera module 1480 or the communication module 1490) functionally related to the auxiliary processor 123.

The memory 1430 may store various data used by at least one component (e.g., the processor 1420 or the sensor module 1476) of the electronic device 1401. The various data may include, for example, software (e.g., the program 1440) and input data or output data for a command related thereto. The memory 1430 may include the volatile memory 1432 or the non-volatile memory 1434.

The program 1440 may be stored in the memory 1430 as software, and may include, for example, an operating system (OS) 1442, middleware 1444, or an application 1446.

The input device 1450 may receive a command or data to be used by other component (e.g., the processor 1420) of the electronic device 1401, from the outside (e.g., a user) of the electronic device 1401. The input device 1450 may include, for example, a microphone, a mouse, a keyboard, or a digital pen (e.g., a stylus pen).

The sound output device 1455 may output sound signals to the outside of the electronic device 1401. The sound output device 1455 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display device 1460 may visually provide information to the outside (e.g., a user) of the electronic device 1401. The display device 1460 may include, for example, a display, a hologram device, or a projector and control circuitry to control a corresponding one of the display, hologram device, and projector. According to an embodiment, the display device 1460 may include touch circuitry adapted to detect a touch, or sensor circuitry (e.g., a pressure sensor) adapted to measure the intensity of force incurred by the touch.

The audio module 1470 may convert a sound into an electrical signal and vice versa. According to an embodiment, the audio module 1470 may obtain the sound via the input device 1450, or output the sound via the sound output device 1455 or a headphone of an external electronic device (e.g., an electronic device 1402) directly (e.g., wiredly) or wirelessly coupled with the electronic device 1401.

The sensor module 1476 may detect an operational state (e.g., power or temperature) of the electronic device 1401 or an environmental state (e.g., a state of a user) external to the electronic device 1301, and then generate an electrical signal or data value corresponding to the detected state. According to an embodiment, the sensor module 1476 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1477 may support one or more specified protocols to be used for the electronic device 1401 to be coupled with the external electronic device (e.g., the electronic device 1402) directly (e.g., wiredly) or wirelessly. According to an embodiment, the interface 1477 may include, for example, a high definition multimedia interface (HDMI), a universal serial bus (USB) interface, a secure digital (SD) card interface, or an audio interface.

A connecting terminal 1478 may include a connector via which the electronic device 1401 may be physically connected with the external electronic device (e.g., the electronic device 1402). According to an embodiment, the connecting terminal 1478 may include, for example, a HDMI connector, a USB connector, a SD card connector, or an audio connector (e.g., a headphone connector).

The haptic module 1479 may convert an electrical signal into a mechanical stimulus (e.g., a vibration or motion) or electrical stimulus which may be recognized by a user via his tactile sensation or kinesthetic sensation. According to an embodiment, the haptic module 1479 may include, for example, a motor, a piezoelectric element, or an electric stimulator.

The camera module 1480 may capture a still image or moving images. According to an embodiment, the camera module 1480 may include one or more lenses, image sensors, image signal processors, or flashes.

The power management module 1488 may manage power supplied to the electronic device 1401. According to one embodiment, the power management module 1488 may be implemented as at least part of, for example, a power management integrated circuit (PMIC).

The battery 1489 may supply power to at least one component of the electronic device 1401. According to an embodiment, the battery 1489 may include, for example, a primary cell which is not rechargeable, a secondary cell which is rechargeable, or a fuel cell.

The communication module 1490 may support establishing a direct (e.g., wired) communication channel or a wireless communication channel between the electronic device 1401 (e.g., 100 of FIG. 1) and the external electronic device (e.g., the electronic device 1402) (e.g., the input device 120 of FIG. 5, the electronic device 1404, or the server 1408) and performing communication via the established communication channel. The communication module 1490 may include one or more communication processors that are operable independently from the processor 1420 (e.g., the application processor (AP)) and supports a direct (e.g., wired) communication or a wireless communication. According to an embodiment, the communication module 1490 may include a wireless communication module 1492 (e.g., a cellular communication module, a short-range wireless communication module, or a global navigation satellite system (GNSS) communication module) or a wired communication module 1494 (e.g., a local area network (LAN) communication module or a power line communication (PLC) module). A corresponding one of these communication modules may communicate with the external electronic device via the first network 1498 (e.g., a short-range communication network, such as Bluetooth™, wireless-fidelity (Wi-Fi) direct, or infrared data association (IrDA)) or the second network 1499 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1492 may identify and authenticate the electronic device 1401 in a communication network, such as the first network 1498 or the second network 1499, using subscriber information (e.g., international mobile subscriber identity (IMSI)) stored in the subscriber identification module 1496.

The antenna module 1497 may transmit or receive a signal or power to or from the outside (e.g., the external electronic device). According to an embodiment, the antenna module 1497 may include one antenna including a radiator formed of a conductor or conductive pattern formed on a substrate (e.g., a printed circuit board (PCB)). According to an embodiment, the antenna module 1497 may include a plurality of antennas. In this case, at least one antenna appropriate for a communication scheme used in a communication network, such as the first network 1498 or the second network 1499, may be selected from the plurality of antennas by, e.g., the communication module 1490. The signal or the power may then be transmitted or received between the communication module 1490 and the external electronic device via the selected at least one antenna. According to an embodiment, other parts (e.g., radio frequency integrated circuit (RFIC)) than the radiator may be further formed as part of the antenna module 1497.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1401 and the external electronic device 1404 via the server 1408 coupled with the second network 1499. Each of the electronic devices 1402 and 1404 may be a device of a same type as, or a different type, from the electronic device 1401. According to an embodiment, all or some of operations to be executed at the electronic device 1401 may be executed at one or more of the external electronic devices 1402, 1404, or 1408. For example, if the electronic device 1401 should perform a function or a service automatically, or in response to a request from a user or another device, the electronic device 1401, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1401. The electronic device 1401 may provide the outcome, with or without further processing of the outcome, as at least part of a reply to the request. To that end, a cloud computing, distributed computing, or client-server computing technology may be used, for example.

The electronic device according to various embodiments may be one of various types of electronic devices. The electronic devices may include at least one of, e.g., a portable communication device (e.g., a smartphone), a computer device, a portable multimedia device, a portable medical device, a camera, a wearable device, or a home appliance. According to an embodiment of the disclosure, the electronic device is not limited to the above-listed embodiments.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1440) including one or more instructions that are stored in a storage medium (e.g., internal memory 136 or external memory 1438) that is readable by a machine (e.g., the computer 101). For example, a processor (e.g., the processor 1420) of the machine (e.g., the electronic device 1401) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described sub components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to various embodiments of the disclosure, there may be provided an electronic device (e.g., the input device 120 of FIG. 5), comprising an elongated housing (e.g., 500 of FIG. 5) forming an elongated first inner space (e.g., S1 of FIG. 5), the housing including a first end (e.g., 500a of FIG. 5), a second end (e.g., 500b of FIG. 5), and a conductive part (e.g., 501 of FIG. 5) disposed between the first end and the second end, an internal structure (e.g., 535 of FIG. 5) positioned in the first inner space S1, at least a portion of the internal structure disposed in the conductive part 501 of the housing and forming an elongated second inner space (e.g., S2 of FIG. 5), a first conductive layer (e.g., 536 of FIG. 5) facing an inner surface of the conductive part 501 of the housing 500 and formed on an outer surface (e.g., 535a of FIG. 5) of the internal structure 535, a non-conductive layer (e.g., 637 of FIG. 6) formed to contact the first conductive layer and the inner surface of the conductive part of the housing, and a wireless communication circuit (e.g., 533b of FIG. 5) positioned in the second inner space S2, electrically connected with the first conductive layer 536, and configured to wirelessly transmit and/or receive a signal using at least a portion of the conductive part 501.

According to various embodiments, the electronic device may further comprise a printed circuit board (e.g., 532 of FIG. 5) disposed inside the second inner space S2. The wireless communication circuit 533b may be mounted on the printed circuit board 532.

According to various embodiments, the electronic device may further comprise a second conductive layer (e.g., 836′ of FIG. 8) formed on an inner surface of the internal structure 535 and electrically connected with the first conductive layer.

According to various embodiments, the electronic device may further comprise a conductive via (e.g., 836″ of FIG. 8) electrically connecting the first conductive layer with the second conductive layer.

According to various embodiments, the electronic device may further comprise a flexible conductive member (e.g., 834 of FIG. 8) positioned between the printed circuit board and the second conductive layer while contacting the printed circuit board and the second conductive layer.

According to various embodiments, the electronic device may further comprise a waterproof sealant (e.g., 540 of FIG. 5) formed on the internal structure 535.

According to various embodiments, the electronic device may further comprise an elastic member (e.g., 638 of FIG. 6) positioned to pressurize the internal structure to the inner surface of the conductive part 501 of the housing 500.

According to various embodiments, the communication circuit may be configured to support a BLE standard.

According to various embodiments, a plurality of first conductive layers may be formed on the outer surface.

According to various embodiments, the first conductive layer (e.g., 536 of FIG. 5) may include a first conductive plate (e.g., 536a of FIG. 5) electrically connected with a power supply unit and a second conductive plate (e.g., 536b of FIG. 5) electrically connected with a ground unit.

According to various embodiments, at least two or more second conductive plates 536b may be provided.

According to various embodiments, the electronic device may further comprise an elongated mold part (e.g., 511 of FIG. 5) having at least a portion positioned inside the first end of the housing and disposed adjacent to a printed circuit board.

According to various embodiments, the electronic device may further comprise a third conductive layer (e.g., 512a of FIG. 5, 712a of FIG. 7A, or 1112a of FIG. 11) formed on an outer surface of the mold part 511.

According to various embodiments, the electronic device may further comprise a conductive line (e.g., 1112b of FIG. 11) electrically connecting the third conductive layer (512a of FIG. 5, 712a of FIG. 7A, or 1112a of FIG. 11) and the communication circuit.

According to various embodiments, the electronic device may further comprise an elastic member (e.g., 1213 of FIG. 12) formed on an outer surface of the mold part and facing the inner surface of the housing.

According to various embodiments, there may be provided an electronic device (e.g., 100 of FIG. 1) including the electronic device (e.g., the input device 120 of FIG. 5). According to various embodiments, the electronic device (e.g., 100 of FIG. 1) may comprise a first housing (e.g., 110 of FIG. 1) (or a main body part) including a first plate (e.g., 102 of FIG. 1), a second plate (e.g., 111 of FIG. 2) facing away from the first plate, and a side member (e.g., 118 of FIG. 1) surrounding a receiving space (e.g., 122 of FIG. 4A) between the first plate 102 and the second plate 111, and an elongated receiving hole (e.g., 121 of FIG. 4A) formed in the side member and connected with the receiving space. The electronic device may further comprise an input device (e.g., 120 of FIG. 4A) inserted into the receiving hole of the electronic device (e.g., 100 of FIG. 1) or removable from the receiving hole. According to various embodiments, the electronic device may comprise an elongated second housing (e.g., 500 of FIG. 5) forming an elongated first inner space (e.g., S1 of FIG. 5), the second housing including a first end (e.g., 500a of FIG. 5), a second end (e.g., 500b of FIG. 5), and a conductive part (e.g., 501 of FIG. 5) disposed between the first end and the second end, an internal structure (e.g., 535 of FIG. 5) positioned in the first inner space S1, at least a portion of the internal structure disposed in the conductive part 501 of the second housing 500 and forming an elongated second inner space (e.g., S2 of FIG. 5), a first conductive layer (e.g., 536 of FIG. 5) facing an inner surface of the conductive part 501 of the second housing 500 and formed on an outer surface of the internal structure 535, a non-conductive layer (e.g., 637 of FIG. 6) formed to contact the first conductive layer and the inner surface of the conductive part 501 of the second housing, and a wireless communication circuit (e.g., 533b of FIG. 5) positioned in the second inner space S2, electrically connected with the first conductive layer 536, and configured to wirelessly transmit and/or receive a signal using at least a portion of the conductive part 501.

According to various embodiments, the electronic device 100 may further comprise a communication module or an electromagnetic induction panel disposed in the first housing 110. The electronic device may receive an input signal from the input device through the communication module or the electromagnetic induction panel.

According to various embodiments, the electronic device 100 may further comprise a processor. The processor may be configured to refrain from processing an input signal received while the input device is in the receiving hole while processing an input signal received while the input device is positioned outside the receiving hole.

According to various embodiments, the communication module may be configured to support a BLE standard.

According to various embodiments, the input device may further include a charging circuit and a battery and may be configured to charge the battery using power received from the electronic device while being received in the receiving hole.

While the present invention has been shown and described with reference to exemplary embodiments thereof, it will be apparent to those of ordinary skill in the art that various changes in form and detail may be made thereto without departing from the spirit and scope of the present invention as defined by the following claims.

1. An input device, comprising:
an elongated housing forming an elongated first inner space, the housing including a first end, a second end, and a conductive part disposed between the first end and the second end;
an internal structure positioned in the first inner space, at least a portion of the internal structure disposed in the conductive part of the housing and forming an elongated second inner space;
a first conductive layer facing an inner surface of the conductive part of the housing and formed on an outer surface of the internal structure;
a non-conductive layer configured to contact the first conductive layer and the inner surface of the conductive part of the housing; and
a wireless communication circuit positioned in the second inner space, electrically connected with the first conductive layer, and configured to wirelessly transmit and/or receive a signal using at least a portion of the conductive part.

2. The input device of claim 1, further comprising a printed circuit board disposed inside the second inner space, wherein the wireless communication circuit is mounted on the printed circuit board.

3. The input device of claim 2, further comprising a second conductive layer formed on an inner surface of the internal structure and electrically connected with the first conductive layer.

4. The input device of claim 3, further comprising a conductive via electrically connecting the first conductive layer with the second conductive layer.

5. The input device of claim 3, further comprising a flexible conductive member positioned between the printed circuit board and the second conductive layer while contacting the printed circuit board and the second conductive layer.

6. The input device of claim 1, further comprising a waterproof sealant formed on the internal structure.

7. The input device of claim 1, further comprising an elastic member positioned to pressurize the internal structure to the inner surface of the conductive part of the housing.

8. The input device of claim 1, wherein the communication circuit is configured to support a Bluetooth low energy (BLE) standard.

9. The input device of claim 1, wherein the first conductive layer includes a first conductive plate electrically connected with a power supply unit and a second conductive plate electrically connected with a ground unit.

10. The input device of claim 1, further comprising an elongated mold part having at least a portion positioned inside the first end of the housing and disposed adjacent to a printed circuit board.

11. The input device of claim 10, further comprising a third conductive layer formed on an outer surface of the mold part.

12. An electronic device comprising the input device of claim 1, the electronic device comprising:
a main body part including a first plate, a second plate facing away from the first plate, and a side member surrounding a receiving space between the first plate and the second plate; and
an elongated receiving hole formed in the side member and connected with the receiving space, wherein the input device is inserted into the receiving hole or is removable from the receiving hole.

13. The electronic device of claim 12, further comprising a communication module or an electromagnetic induction panel disposed in the main body part, wherein the electronic device is configured to receive an input signal from the input device through the communication module or the electromagnetic induction panel.

14. The electronic device of claim 12, further comprising a processor, wherein the processor is configured to refrain from processing an input signal received while the input device is in the receiving hole and is configured to process an input signal received while the input device is positioned outside the receiving hole.

15. The electronic device of claim 12, wherein the input device further includes a charging circuit and a battery, and wherein the input device is configured to charge the battery with power received from the electronic device while being in the receiving hole.
